(19) United States
(12) Patent Application Publication
(10) Pub. No.: US 2016/0056363 A1
(43) Pub. Date: Feb. 25, 2016

(54) Freestanding Thermoelectric Energy Conversion Device

(71) Applicants: The Penn State Research Foundation, University Park, PA (US); Impulse Technology LLC, State College, PA (US)

(72) Inventors: Md Amanul Haque, State College, PA (US); Md Tarekul Alam, State College, PA (US); Mst Kamrunnahar, State College, PA (US)

(21) Appl. No.: 14/816,240

(22) Filed: Aug. 3, 2015

Related U.S. Application Data
(60) Provisional application No. 62/040,059, filed on Aug. 21, 2014.

(51) Int. Cl. H01L 35/32; H01L 35/34

(52) U.S. Cl. CPC H01L 35/32; H01L 35/34

(57) ABSTRACT

A thermal to electrical energy conversion device has freestanding thin or thick films of thermoelectric materials, n or p type or both, extending from thermally conducting and electrically insulating substrates. The freestanding thermoelectric elements exploit up to two orders of magnitude higher free convective heat transfer coefficient and thermal resistance. The combined effect is very large temperature differential not possible with prior art unless an auxiliary cooling mechanism (pumped liquid or fanned air) is used. The large temperature differential results in higher efficiency and power output. Methods of making these thermal electric conversion devices are also disclosed.

### STATEMENT OF GOVERNMENT LICENSE RIGHTS

This invention was made with government support under Grant Nos. ECCS 1028521 and IIP-1417173, awarded by the National Science Foundation, USA. The Government has certain rights in the invention.

### FIELD OF THE INVENTION

The present disclosure is directed towards devices that increase the efficiency of Thermo-electric Energy (“TE”) Conversion in which waste heat is converted to electricity.

### BACKGROUND OF THE INVENTION

The total amount of heat energy wasted in the United States is about 60-70 quadrillion BTU/year, equivalent to a loss of $6 billion per year. Harvesting even 20% of that waste heat would be comparable to adding 10-30 nuclear power plants. Thermo-electric energy conversion is a green (zero emission, operation and maintenance) technology to harvest electricity from waste heat. However, the conversion efficiency is often less than 10%, and to be commercially sustainable, this has to be improved to 30-40%, which is the efficiency of state of the art combustion or power generation cycles. Such efficiency has been elusive for TE conversion products even after six decades of research.

TE conversion is a technology that converts heat to electricity. FIG. 1 shows the basic principle, where two thermoelectric materials, denoted by n and p, connect a heat source with hotter temperature Tₕ to a heat sink with colder temperature T_{c}. The open circuit voltage, V, obtained from the device is equal to the product of the temperature difference, ΔT=Tₕ−T_{c}, and the ‘Seebeck’ coefficient, ‘S’, of the materials. In FIG. 1, the n type and p type thermoelectric materials are connected in series, so the voltage is given as V=(Tₕ−T_{c})*(Sₙ+Sₚ). However, the thermoelectric materials have their own internal resistance, which depends on electrical conductivity, “σ” of the material. This internal resistance self-consumes the thermoelectric power to further reduce the efficiency of energy conversion. The existing approach towards efficiency is to develop new materials with high values of thermoelectric figure of merit, known as ZT. “T” here represents temperature and the term “Z” is a measure of the thermopower, represented as S²σ. Hence, very large S and o are needed for large voltage output and small internal loss, while very small thermal conductivity, represented as κ, is needed for large temperature difference. These characteristics are the goals of Thermoelectric Energy (TE) conversion. However, having very large S and σ, along with very small κ, is currently known as being mutually exclusive. There are numerous publications which report that in the materials that were tested heat and current transport are inherently coupled and inversely related to Seebeck coefficient, S. Decoupling of electrical and thermal conductivity has not been accomplished prior to the present disclosure.

The past six decades of work in the area of TE conversion has led to multipronged research to identify materials that have higher ZT values. Current efforts are focused on development of new materials to obtain the ZT greater than 3. At that value, the technology will be commercially viable. FIG. 2 is a graph which shows the values of ZT that have been reported for several materials and the years they were discovered or first proposed. As can be seen in FIG. 2, even though materials having a ZT value near 2.5 exist, they are complex and expensive for technological implementation. As shown in FIG. 3a, these materials are effective for only a narrow range of temperatures. For example, PbTe has a ZT of about 1.8 but is not very effective outside the temperature range of 450° C. plus or minus 50° C.

A major drawback of the current TE conversion technology is the inability to create or sustain a large temperature difference. This is because the thermal conductivity of existing materials are not low enough to create the desired temperature gradient. Since Carnot (maximum theoretical) efficiency=(Tₕ−T_{c})/Tₕ, small temperature difference results in low efficiency. Current practice is therefore to use a heat sink and externally flow air or water through the cold end to maintain a large temperature differential. Current manufacturers do not account for the space and power required for this auxiliary system for ‘cooling the cold end’. Rather, the power output is quoted on the assumption of a temperature difference that is externally applied and maintained with an auxiliary cooling system with feedback control. The pumps or fans in such auxiliary system needs some space to install and adds daily operating cost to the technology (ideally TE conversion technology is zero operating and maintenance cost) and decreases true system efficiency. It is this observation that motivates the present invention, which does not need any such auxiliary cooling system. A major benefit or claim of the present invention is therefore, if the product that we disclose here and any prior art product are kept on the same hot surface temperature and no external control is applied on the cold end, our product will produce more power per unit area compared to the prior art product.

Another major drawback of the current TE conversion technology is inefficient assembly design, where typically less than 100 unit TE cells are assembled per square inch. Current TE conversion manufacturing involves machining of macroscopic n and p type thermoelectric blocks and their assembly in a serial manner. Unless thin film technology is used, the layout of current TE conversion device manufacturing is not amenable to massive scaling and miniaturization. In addition to the low efficiency, the current generation TE conversion devices suffer from low power density, due to the number of thermoelectric elements or ‘legs’ per unit area, and high cost, in terms of dollars per watts generated.

Thus, there is a need for TE conversion devices having more efficient energy conversion attributes without auxiliary cooling systems that consume both space and power and better, less expensive manufacturing techniques for such devices. There is also a need for a more efficient TE conversion device that can be reliably produced in commercial quantities.

### SUMMARY OF THE INVENTION

We provide a device for thermoelectric conversion of energy which can be attached to a hot structure and convert heat energy from that structure into electrical energy. The device is completely different from the prior art in design. It is also different in operation since it does not need any external control or manipulation of the cold end temperature. FIG. 3b shows structure and design of a conventional TE conversion device. In comparison, two representative embodiments of the present invention are shown in FIGS. 5 and 9. Here, the thermoelectric elements (both n and p type) are shown as ‘freestanding’ (clamped at both ends as in FIG. 5, or at one end as in FIG. 9) bridge structures and made of thin/thick films of thermoelectric materials. The thickness of the thermoelectric elements can vary from 50 nanometers to 500 micrometers. It is important to note that some of the prior art products do contain thin or thick film based designs, but these elements are not freestanding. The unique freestanding aspect of the present invention gives rise to two advantages not possible with prior art:
(i) The freestanding thin/thick film structures have higher free convective heat transfer coefficient (known as the term ‘h’). For prior art, h can be at most 20 W m⁻² K⁻¹. In comparison, the present invention exploits the size dependence of the h value, which increases as the thickness of the thermoelectric element becomes smaller. For example, we have measured h as high as 4000 W m⁻² K⁻¹ for an element of 20×10 micron² cross section element.
(ii) The freestanding thin/thick film structures have higher thermal and electrical resistance. Denoted by Rₜₕ, thermal resistance is given by Rₜₕ=x/(Aκ), where x is the length of the thermoelectric element (along the path of heat flow), κ is the thermal conductivity of the material and A is the cross-sectional area (perpendicular to the path of heat flow). This highly nonlinear function yields very high thermal resistance with decrease in the cross-sectional area. For example, a 5 mm long bismuth telluride bar with 1.5×1 5 mm² cross section has thermal resistance of 1100° K/W, while 100×100 micron² cross-section will yield 250,000° K/W.

The combined effect of the (i) increased free convection heat loss and (ii) increased thermal resistance results in very large temperature drop in the thin/thick films of thermoelectric elements as configured in FIG. 5 or 9. It is important to note that the electrical resistance also increases with decrease in the thermoelectric cross-sectional area. However, the effect of thermal resistance scales as a squared function when power output is calculated. This is because power output is a squared function of the temperature difference. The effect of electrical resistance, on the other hand is linear. For example, 100 times increase in thermal resistance would positively influence 10,000 times through temperature difference, while negatively influence 100 times through increase in electrical resistance, therefore then net increase in power is 100 times. This is shown by the following equation:

$$P = Δ {T}^{2} \frac{{S}^{2}}{ρ} \frac{A}{l}$$

Where, ρ, A and l are resistivity, cross-section area and length of the thermoelectric legs. Another unique feature of the present invention is that miniaturization can be exploited to manufacture the freestanding thin/thick film thermoelectric devices in the same way as microelectronic devices. Miniaturization, as shown later, allows the thermoelectric elements to be assembled as both series and parallel configurations. While the prior art always embodies thermoelectric elements connected in series to increase the output voltage, our design allows their parallel combination as well to reduce the total internal resistance for applications where low resistances are required. Since a single thermoelectric element acts as a voltage source, parallel configuration can be used to reduce the electrical resistance. In such design, a set on thermoelectric elements are connected as parallel (inset of FIG. 7a), while such sets are added in series. This unique aspect allows our products to control the total internal resistance of the product.

It is important to note that a major class of devices in the prior art involve thin or thick film thermoelectric elements. However, these films are laid out on solid supports (or substrates). Since these thermoelectric elements are not freestanding but rather attached to a substrate, they essentially have the same temperature as the substrate. This is because their very small thermal masses are insignificant, compared to the very large thermal mass of the substrate. This causes very small temperature differential, which can be shown easily experimentally and theoretically.

It is also important to note that the present invention improves thermoelectric energy conversion efficiency and power output through unique design, even with existing materials such as bismuth telluride. The present invention will produce even better results with new materials innovation (with higher ZT) as they become available in the future for technological implementation.

A first embodiment of our device has a metal pad positioned between and spaced apart from the metal plates. A first n-type leg has one end attached to the first metal plate and an opposite end attached to the metal pad. A first p-type leg has one end attached to the second metal plate and an opposite end attached to the metal pad. A second n-type leg has one end attached to the first metal plate and an opposite end attached to the metal pad. A second p-type leg has one end attached to the second metal plate and an opposite end attached to the metal pad. The metal pad is spaced apart from the heated surface and is cold relative to the heated surface. Leads extend from each metal plate which can be connected to a load. The temperature differential between the metal plates which have been attached to a hot structure and the cold metal pad causes a voltage bias and current to flow.

A second embodiment of our device for thermoelectric conversion of energy has a set of grates stacked on one another. Each grate consists of a semiconductor layer on a carrier. The semiconductor layer has a p-side and adjacent n-side. The layer is cut to provide a series of spaced apart bars extending between a p-side and an n-side. The carrier has an open center which allows air to pass between the bars. The grates are stacked in alternating fashion so that the p-side of one grate is opposite the n-side of the adjacent grate. Adjacent grates are connected together in a manner to allow current to flow from one grate to the next grate. Opposite sides of the stack are attached to a hot surface. This embodiment is similar to the first embodiment without the metal pad.

A third embodiment of our device for thermoelectric conversion of energy has a single metal plate and a series of legs extending outward from the metal plate. Each leg consisted of a p-type layer, a glass layer and an n-type layer. The proximate end of each leg is attached to the one side metal plate and becomes the hot end when the metal plate is attached to a hot structure. The distal end of each leg is free and has a conductive material on that end which allows current to flow between the p-type layer and the n-type layer. The legs are attached to the metal plate so that the p-type layer is alternately facing up and then facing down. Adjacent legs are connected together at their proximate ends so that current can flow from one leg to the next leg. Preferably there are two sets of legs, one set of legs attached to one side of the metal plate and the second set of legs connected to the opposite side of the metal plate.

The metal plates and metal pads preferably are copper. The n-type leg is preferably bismuth telluride and the p-type leg is preferably antimony telluride for low temperature range applications. For higher temperature ranges, lead telluride or silicon-germanium can be used. A significant advantage of this invention is that existing materials can be used to enhance efficiency. The insulators are preferably silicon nitride. If desired, a silicon substrate may be provided between the insulators and the hot structure.

The first embodiment can be made through a chemical deposition process in which silicon nitride is vapor deposited on a silicon chip and chemically etched to form the insulators. Then copper is deposited on the insulators. The n-type legs and p-type legs are films that are printed between the metal pad and one of the metal plates. Then a portion of the silicon chip below the metal pad is etched away which allows air to flow around the metal pad.

The second and third embodiments can be made from slabs of material which cut to create the legs or bars. Preferably a laser is used to cut the slabs.

Other objects and advantages of the present invention will become apparent from a description of certain present preferred embodiments shown in the drawings.

### BRIEF DESCRIPTION OF THE DRAWINGS

FIG. 1 is an electrical circuit diagram that applies to many prior art TE conversion devices as well as the devices here disclosed.

FIG. 2 is a graph of the ZT values of various prior art materials and the year they were discovered;

FIG. 3a is a graph of the figures of merit versus temperature for various prior art materials shown in FIG. 2;

FIG. 3b is a perspective view of a TE conversion device known in the art.

FIG. 4a is a perspective view of an experimental set up to prove the concept that a freestanding, bridge shaped thin or thick film will experience higher temperature differential compared to a counterpart that is attached to a substrate. Current art is to have thermoelectric films on a substrate. The freestanding thin/thick film is therefore is portion of a TE conversion cell according to a preferred embodiment of the present disclosure;

FIG. 4b is a graph of the temperatures at selected locations of the TE conversion cell shown in FIG. 4a.

FIG. 5 is a perspective view of a single TE conversion cell of a TE conversion device according to preferred embodiment of the present disclosure;

FIG. 6a is a perspective view of a portion of a COMSOL multiphysics finite element model of our TE conversion cell similar to that shown in FIG. 5.

FIG. 6b is a graph of the temperatures along the length of the leg of the cell shown in FIG. 6a when the metal plates are heated to three selected temperatures.

FIG. 7a is a perspective view of a portion of a second present preferred embodiment of our TE conversion device.

FIG. 7b is a graph of the heat flux along the length of the leg of the cell shown in FIG. 7a when the metal plates are heated to three selected temperatures.

FIG. 7c is a perspective view and a portion of a third present preferred embodiment of our TE conversion device.

FIG. 7d is a perspective view and a portion of a fourth present preferred embodiment of our TE conversion device.

FIG. 8 is a flow diagram of a present preferred method of manufacturing the TE conversion device shown in FIG. 5.

FIG. 9 is a perspective view and a fifth present preferred embodiment of our TE conversion device.

FIG. 10 is a flow diagram of a present preferred method of manufacturing the TE conversion device shown in FIG. 9.

FIG. 11 is a perspective view and a sixth present preferred embodiment of our TE conversion device.

FIG. 12 is a flow diagram of a present preferred method of manufacturing the TE conversion device shown in FIG. 11.

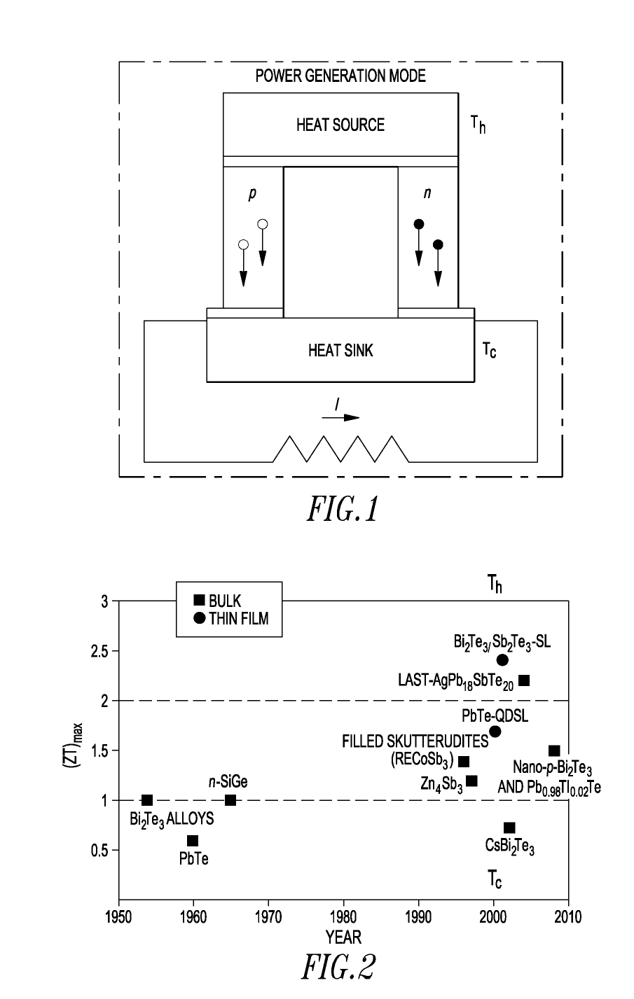

### DETAILED DESCRIPTION OF THE PREFERRED EMBODIMENTS OF THE INVENTION

The efficiency (η) and output power (P) of a TE conversion cell is given by the following equations:

$$\begin{matrix}η = \frac{{T}_{h} - {T}_{c}}{{T}_{h}} \frac{\sqrt{1 + Z \frac{( {T}_{h} + {T}_{c} )}{2}} - 1}{\sqrt{1 + Z \frac{( {T}_{h} + {T}_{c} )}{2}} + \frac{{T}_{c}}{{T}_{h}}} & ( 1 ) \\ P = {V}^{2} \div R = Δ {T}^{2} {S}_{n}^{2} {σ}_{n} \frac{{A}_{c}}{4 L} + Δ {T}^{2} {S}_{p}^{2} {σ}_{p} \frac{{A}_{c}}{4 L} & ( 2 )\end{matrix}$$

where, Z=S²σ/κ, S is the Seebeck coefficient, σ and κ are electrical and thermal conductivities. The n and p type TE conversion legs, which are denoted by subscripts, have cross-sectional area A_{c} and length L. The constant 4 is based on a matched load (the external electrical resistance of the application is same as the internal resistance of the thermoelectric legs) assumption.

The approach of the present invention is different from the prior art. Rather than specifically targeting ZT, the focus is shifted to the temperature differential: ΔT=Tₕ−T_{c}. Also, the approach is to minimize the cold end temperature by minimizing thermal conductivity, and not just cooling it with an additional cooling system. The rationale is that efficiency is a stronger function of ΔT than ZT. This is shown by resorting to the equation below:

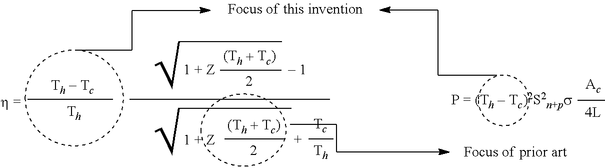

The equation above implies that higher ΔT is needed for higher efficiency. It is noted that most TE conversion applications employ a TE conversion device with a hot side attached to a hot surface. If the hot side is few hundred degrees above ambient, the material will need to have ultra-low thermal conductivity to have a cold side temperature that is equal to ambient. Since no such low thermal conductivity thermoelectric materials exists yet, the current art is to externally manipulate the cold end temperature by cooling it with water, air or other coolants. However, such cooling requires installation and operation of an entire new cooling system that may be difficult and costly. Any such external cooling system also has operating costs per hour, which means the TE conversion is not a zero operating or maintenance technology anymore.

The present disclosure applies the familiar principle that a ‘bridge ices before the road’. This is because the bridge has both the top and bottom surfaces exposed to air, losing more heat than the road does. In addition, the present invention applies a micro/nano scale phenomenon that the thinner and/or longer the bridge is, the higher the heat loss from it. This phenomenon is orders of magnitude stronger at the micro and nano scales, where (i) heat transfer coefficient is >100 times larger and (ii) surface area to volume ratio can be >100 times larger too.

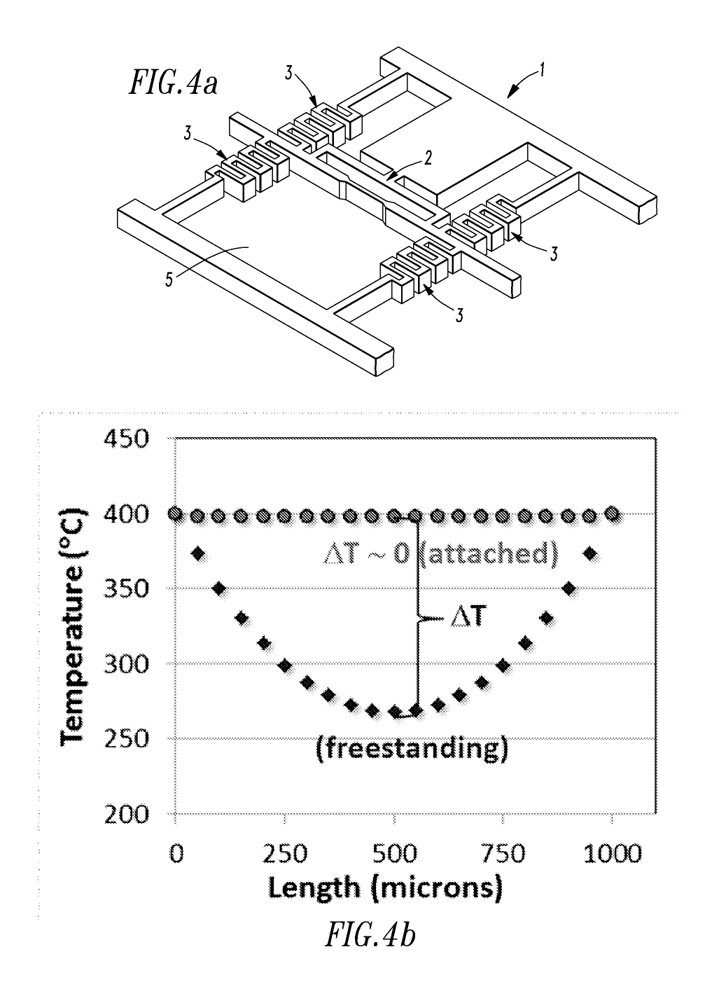

A demonstration made coating the structure shown in FIG. 4a with a 200 nm thick nickel film. Thus, the nickel film is attached to the structure (also called as ‘substrate’) everywhere. However, the substrate below the nickel film in location label 1 was removed using chemical etching to form a freestanding nickel film similar to a bridge. Parallel to this ‘bridge’, a ‘road’ 2 was fabricated using an identical film but attached to the silicon substrate. An infrared thermal image was taken after the bridge 1 and road 2 were heated with two micro-heaters 3 at 400° C. which were spaced 1000 microns apart. The thermal image showed that temperatures in the freestanding regions 2 were lower than the temperatures of the micro heaters 3 and the road 2. The temperature profile is plotted in FIG. 4b. Even though nickel is a very good thermal conductor (with κ=90 W/m-K), the middle of the bridge 1 showed a remarkable ΔT=130 K, while the road 2 showed ΔT≈0 K. Embodiments of the present disclosure may be employed using other freestanding films of micro to nano scale geometries. For example, very large ΔT can be obtained in thicker (10-20 microns) thermoelectric film strips (with κ≈1.5 W/m-K) by making them freestanding. Because of the cooling efficiency of the design described, there is no need for external cooling system to achieve and maintain cold end temperature.

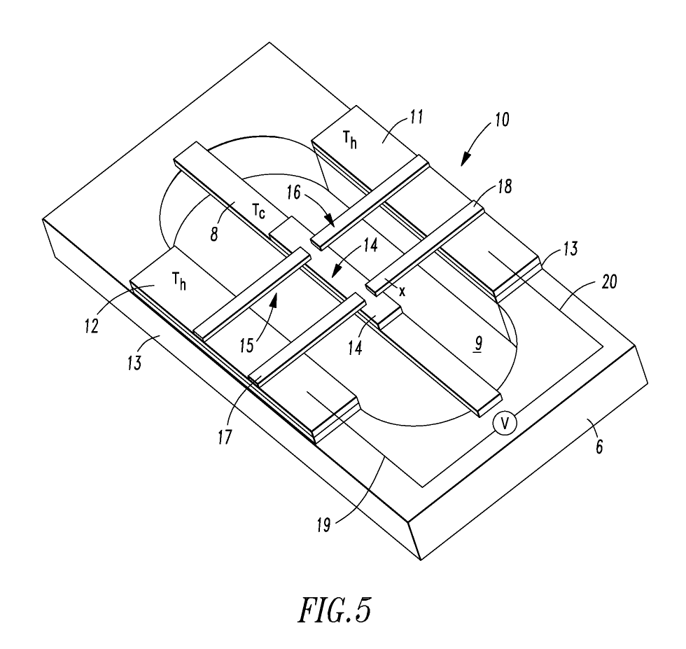

FIG. 5 shows a first present preferred embodiment of our device 10 for thermoelectric conversion of energy, sometimes identified as TE conversion, which can be attached to a hot structure and convert heat energy from that structure into electrical energy. The device can be attached directly to a hot surface but we prefer to provide a host structure 6 that is provided between the hot surface and the device. The host structure 6 preferably has an open (air) region 9. This device has two spaced apart metal plates 11, 12 that form a hot junction indicated by Tₕ and a metal pad 14 that forms a cold junction indicated by T_{c} positioned between and spaced apart from the metal plates or pads. An insulator 13 that provides electrical insulation and allows heat to pass through the insulator is attached to the bottom surface of each metal plate 11, 12. A first n-type leg 15 has one end attached to one plate 12 and an opposite end attached to the metal pad 14. A first p-type leg 16 has one end attached to the other metal plate 11 and an opposite end attached to the metal pad 14. A second n-type leg 17 has one end attached to metal plate 12 and an opposite end attached to the metal pad 14. A second p-type leg 18 has one end attached to metal plate 11 and an opposite end attached to the metal pad 14. The metal pad 14 is spaced apart from the heated surface and is therefore cool relative to the heated surface because of the principle described before. Leads 19, 20 extend from each metal plate. The temperature differential between the metal plates which have been attached to a hot substrate and the cool metal pad causes a voltage bias (V) and current to flow. When these leads are connected with an external load, current flows through it. Or, when they are connected with a battery, the produced power can charge it for future usage. Multiple cells can be connected in series to provide greater amounts of current for a desired power output and application.

In the embodiment of FIG. 5 the device is positioned on a host structure 6 that is then attached to a hot surface. The host structure should allow heat to easily pass through it and may be a silicon wafer. This host structure is open around the metal pad. An electrically and thermally insulating bridge 8 supports the metal pad 14 above the opening in the substrate. The host structure may be omitted in some applications in which the metal plates are attached directly to the heated surface. The metal plates 11, 12 and metal pads 14 preferably are copper. The n-type legs 15, 17 are preferably bismuth telluride and the p-type 16, 18 legs are preferably antimony telluride. The insulators 13 are preferably silicon nitride.

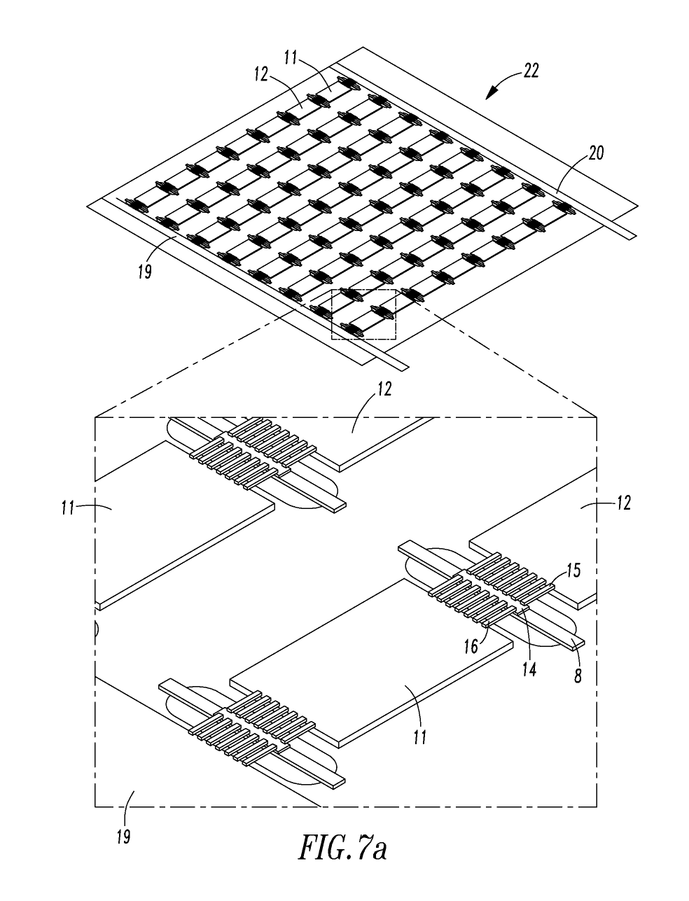

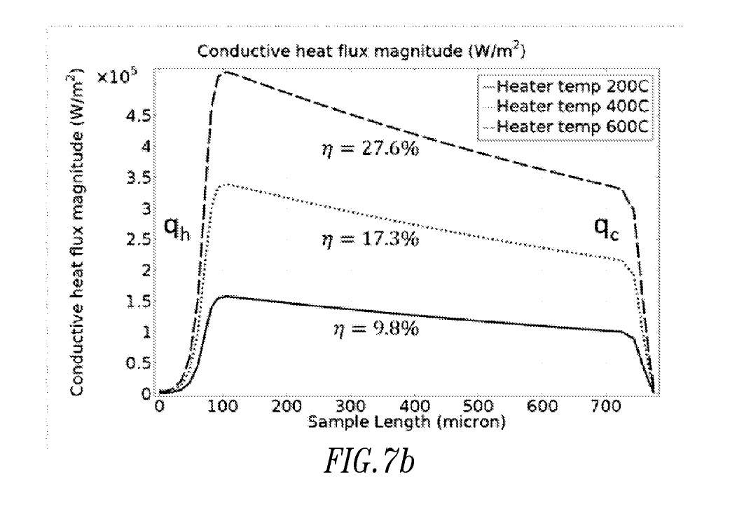

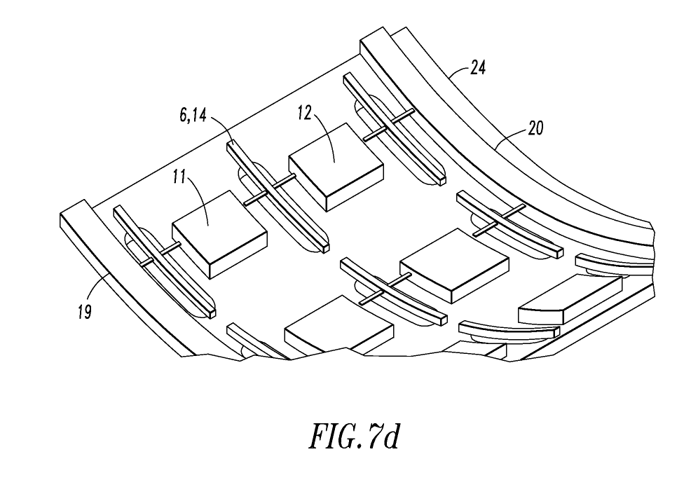

It is expected that the TE conversion film strips will have higher electrical resistance compared to bulk TE conversion legs, causing internal power losses. A unique feature of the design of the present disclosure is that the TE conversion units can be connected in both parallel (to decrease effective electrical resistance) as well as series (to increase voltage output). FIG. 5 shows two sets of parallel legs in one device units to illustrate this concept. Another exemplary embodiment is shown in FIG. 7a. In this embodiment multiple metal plate 11, 12 and metal pads are connected together in series and arranged in parallel to create a single layer chip 22.

We nano-fabricated a structure similar to that shown in FIG. 5 in a laboratory. A finite element multi-physics model indicates 9.8% efficiency for 20 micron thick, freestanding thermoelectric films (assuming ZT=0.15) on a 200° C. surface. Comparatively, existing technology with ZT=0.5 achieves ˜3% efficiency at this temperature. The efficiency increases to 27.6% if the hot surface temperature is raised to 600° C., making the technology sustainable. Further improvements are possible with higher ZT materials. The electrical circuit equivalence of the device shown in FIG. 5 is similar to the circuit shown in FIG. 1. Power output is shown as being obtained from hot junctions in FIG. 5 but this is for sketching convenience only since the leads 19, 20 can also be drawn from cold electrodes or junctions from the neighboring cell.

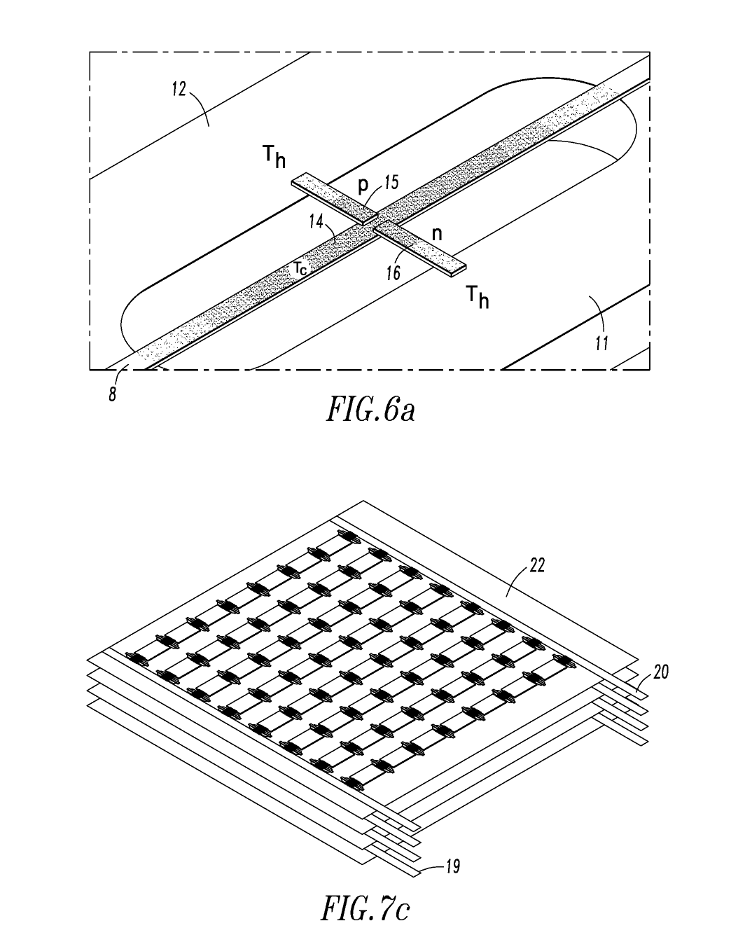

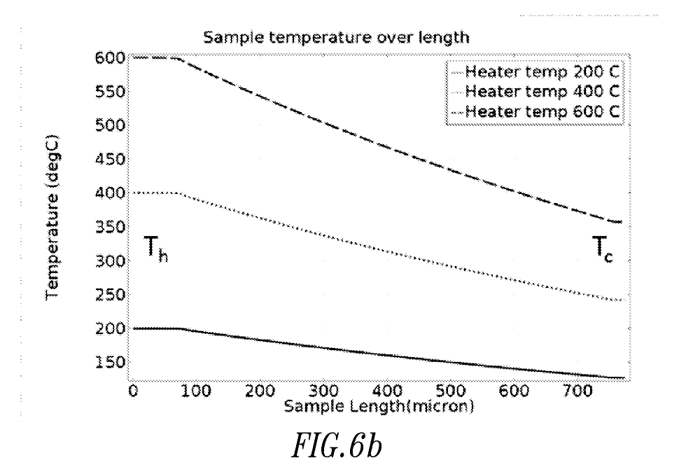

FIG. 6a shows a multi-physics finite element (“COMSOL”) model for the embodiment described above in which the stippling becomes darker as the region becomes cooler. In this model, and in preferred embodiments of the present invention, the substrate is silicon with a thin layer of silicon nitride for electrical isolation and support for the cold junction. Since silicon is a high thermal conductivity material, the entire chip assumes a completely uniform temperature field that is the same as the host hot surface temperature. In addition, a polymeric substrate can be used for flexible TE conversion applications, such as, for example, the embodiment shown in FIG. 7c. The inset of FIG. 6a shows how the two thermoelectric strips are anchored at the cold junction. The materials properties for this model are based on powder-compacted films and are given in Table 1.

TABLE 1

| | | | Thermal |
|---|---|---|---|
| Material | Seebeck coeff. | Electrical resistivity | conductivity |
| n-type Bismuth | 170 μV/K | 5 × 10⁻⁵ ohm-m | 1.2 W/m-K |
| Telluride | | | |
| p-type Antimony | 75 μV/K | 1 × 10⁻⁵ ohm-m | 1.2 W/m-K |
| Telluride | | | |

It should be noted that these values, yielding room temperature ZT=0.15, may be considered conservative since bulk ZT value is around 0.5.

FIG. 6b shows the temperature profile of a single n-type freestanding thermoelectric film strip. The strip is 750 microns long, 50 micron wide and 20 micron thick. For hot surface temperature of only 200° C., the effective ΔT=80 K and the resulting voltage (V=S*ΔT) and resistance are 13.6 mV and 37.5Ω respectively for the n type strip. A unit TE conversion contains two (n and p) of these strips. After including the p-type strip, an output voltage and power rating for a unit TE conversion strip of 27.2 mV and 9.8 μW are obtained.

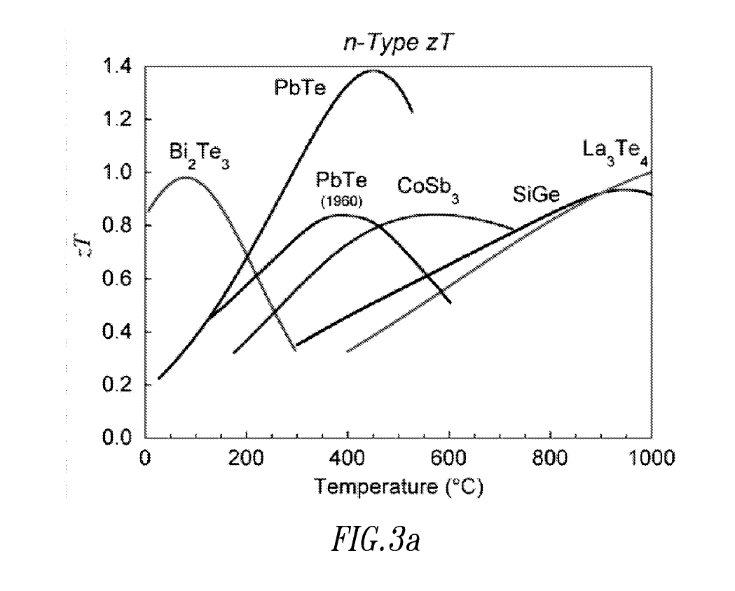

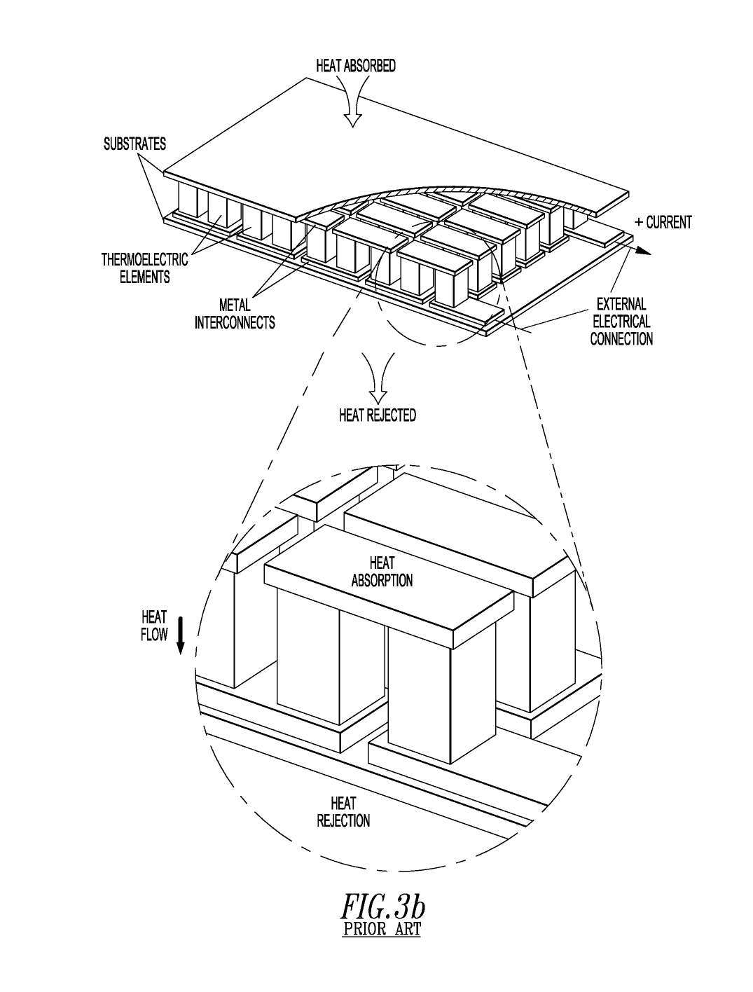

To calculate the efficiency, we note that the energy balance of proposed configuration is very different from that for the bulk TE conversion configuration. Here, a large ΔT is generated out of a uniformly hot surface (ΔT=0 in a conventional sense). The reason a large ΔT is obtained is because the pronounced micro-scale effects of free convective heat loss from the film. Because of this basic difference, the bulk TE conversion efficiency equation is not appropriate. Rather, a more fundamental energy balance approach should be used. The efficiency of a freestanding film TE conversion unit is therefore:

$${η}_{freestanding} = \frac{Power output from Δ T}{Convective heat removed to create Δ T} = \frac{P}{( {q}_{h} - {q}_{c} ) {A}_{c}} \qquad ( 3 )$$

where P is the output power in equation (2) shown above. The source or input behind this output is the convective heat loss from the freestanding film (without convective heat loss, there is no ΔT and no output power). Therefore, 100% efficiency implies that 100% of the convective heat leaving the film strip is converted to electrical energy. The convective heat can be obtained by an energy balance, which is the difference between input and output heat flux times the cross-sectional area, on the film strip. FIG. 3a shows the COMSOL output for the heat flux. For 200° C. hot surface temperature, qₕ=1.5×10⁵ W/m², q_{c}=1×10⁵ W/m², and cross-sectional area of the thermoelectric (n and p) film strip A_{c}=1×10⁻⁹ m² make the convective heat loss Q_{c}=100 μW. In return, the thermoelectric power obtained is P=9.8 μW, which implies efficiency of about 9.8%. The bulk TE conversion efficiency based on ZT=0.5 is estimated to be only 3% at this temperature.

Similar analysis can be performed for higher temperatures. FIGS. 6b and 7b show results for three different hot surface temperatures. At 600° C., the efficiency and power output increase to 27.6% and about 48 micro-Watts. This is quite expected because ΔT increases by 3 times compared to 200° C. and efficiency and power scale as ΔT and ΔT² respectively. These idealized results are very encouraging because they are based on ZT=0.15 only. Further improvement in thin film ZT may be possible through research.

It is envisioned that the commercial product manufacturing will be dominated by the high speed printing of thermoelectric and metal electrode films. These processes are highly scalable, and so is the product design. FIG. 7c shows how stacking of the ˜0.5 mm thick single layer chips result in high power and power density. FIG. 7d shows possible wrapping of TE conversion layers (around a heated pipe) using a flexible substrate. For a stacked product, we can compare the 600° C. performance with that for an internal combustion engine. At this temperature, a 0.5 mm thick layer (50×100×100 TE conversion strips, ΔT=250 K) generates 25 W power. A final stacked product of size 150 mm×150 mm×25 mm is expected to produce at least 1 kW considering interlayer gaps and losses. The power density of about 2.3 W/cc is smaller than 50 W/cc for a 3 L engine with 200 HP rating. However, the real advantage is the power per unit weight (850 W/kg for the proposed TE conversion compared to the 750 W/kg for an assumed 200 kg engine). Tremendous potential, therefore, exists for this technology with further improvement in ZT.

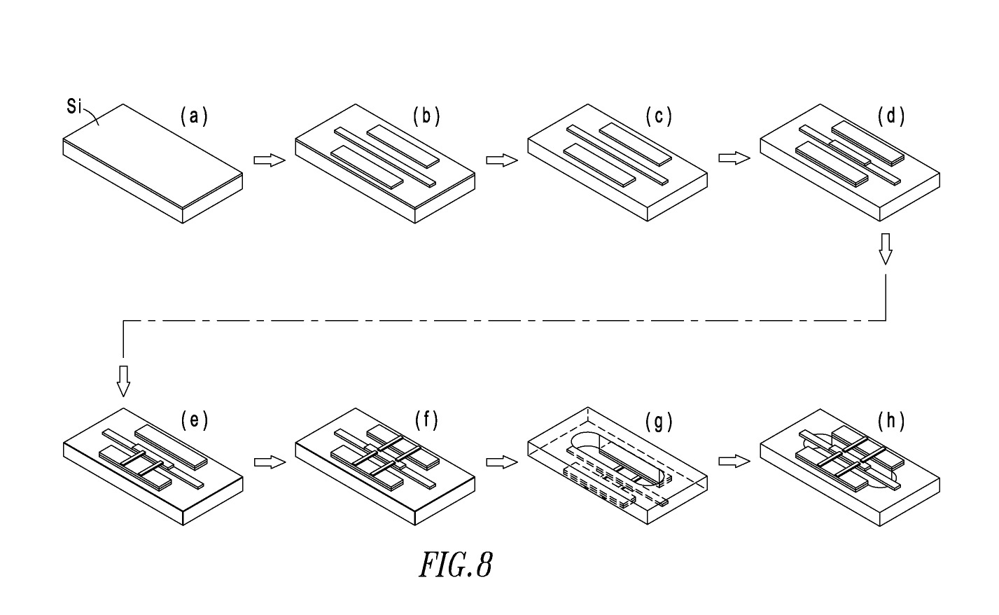

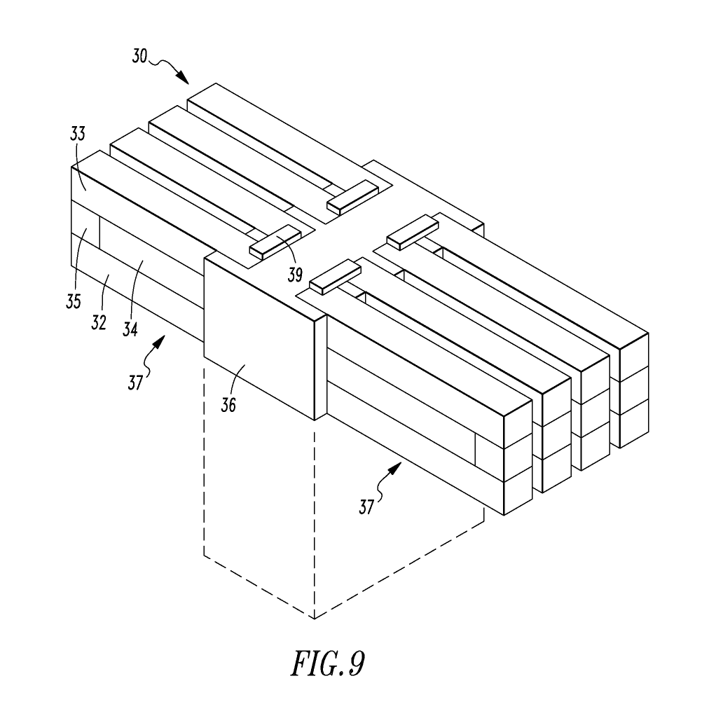

FIG. 8 shows one possible embodiment of fabrication processing steps for a TE conversion device according to the present invention. The embodiment discussed may be considered a hybrid of conventional micro-fabrication and high throughput printing of thermoelectric films. The process allows large batch fabrication operations with ultrafast and cost effective electronic printing to reduce overall production costs.

As shown in FIG. 8, the fabrication process starts with (a) deposition and (b) patterning of silicon nitride on the wafer. Preferably vapor deposition is used to deposit the silicon nitride. The silicon nitride is etched in step (c) to create three substantially parallel segments of silicon nitride on the silicon substrate. Then electrode material such as copper is (d) deposited on the nitride layer and patterned for the electrical interconnects. This creates a first metal plate, a second metal plate and a metal pad between the first metal plate and the second metal plate. The next step (e) is to print a layout of the n (bismuth telluride, Bi₂Te₃) type film and then (f) to print a layout of the p (antimony telluride, Sb₂Te₃) type film. This creates the n-type legs between the first metal plate and the metal pad and creates the p-type legs between the metal pad and the second metal plate. The thin films can be 3D/screen printed with a screen or inkjet or 3D printer. The ink will be created by binding the nanopowders with polymeric binders (for example ethylene glycol or polymethylmethacrylate) with desired viscosity such as 1500-2000 centipoise. The printers typically have minimum feature width and thickness values of 10 microns and 100 nm respectively, which will be satisfactory for our design. From commercialization perspective, this technique is more attractive than electro-deposition because of its very high throughput (highest print speed 100 mm/s; no lithography or etching) technology and larger Seebeck coefficient values. These materials are then cured by vacuum annealing at up to 300° C. After that, backside lithography is used to create a photoresist pattern on the backside of the silicon (g). That is followed by deep reactive ion etching (DRIE) removes the silicon underneath the thermoelectric films in step (h). This step makes both the nitride bridge with the cold side electrode and the thermoelectric films freestanding.

The similar principle described above can be used for thermoelectric cooling as well, where power is externally supplied to create a temperature differential (opposite of power generation). Here, the challenge is to maintain the cold side temperature so that the heat does not leak back. To maintain a large temperature difference, a constriction will preferably comprise a large and abrupt change in cross-sectional area of the legs. For example, a reduction from a 5 mm², which is typical size of a TE conversion leg in a current device, cross-section to 500 μm² size represents a 100 times reduction in cross-sectional area. Redesigning the geometry of the current millimeter-scale TE conversion legs is not expected to produce substantial performance gains. A very large value that may not be possible at the macro scale, for example a 40,000:1 area change in a single step, may be more easily achieved at the micro and nano scales. According to the present disclosure, a large and abrupt change in cross-sectional area is easier to achieve with a TE conversion device that has micron-scale legs with nano scale heat chokes. Furthermore, replacing 5 mm size legs in TE conversion device with 20 μm legs implies that a very large increase in leg density will be present as well.

A single-step reduction from a 20 μm² cross-sectional area to 200 nm² cross-sectional area represents reduction in the area by a factor of 10,000. A large change in temperature, 50° C., may take place at the constriction. Comparatively, a gradual change in the same dimension causes a temperature change of only 30° C.

The legs may be created or formed integrally and may be created from the same or different thermoelectric materials. In the present preferred embodiment, the thermoelectric material is a semiconductor, such as, for example, silicon. Additionally, the thermoelectric material may be one of Bi₂Te₃ and Sb₂Te₃. Materials that are good conductors of current and can be constructed in the appropriate size range are generally suitable. These materials will exhibit large electrical conductivity and have a large Seebeck coefficient for optimal performance. Even with these, and other existing thermoelectric materials, by employing the geometry enhanced technique according to the present disclosure, one can achieve efficiency that is higher than the state of the art technology.

In the embodiment shown in FIG. 5, each leg preferably has a constriction or choke. The constrictions are sized and configured as discussed above. The temperature drop, ΔT, in a constriction-based TE conversion design can be related to the heat flow rate, represented by P, and thermal resistance, Rₜₕ. The heat flow rate is obtained by:

$${Q}_{i} = κ A \frac{d θ}{d x} {\vert}_{i} = κ Am ( {θ}_{i} + {θ}_{L} ) ( \frac{cosh ( mL ) - 1}{sinh ( mL )} )$$

$$θ = T ( x ) - {T}_{∞} and m = \sqrt{\frac{2 h ( w + t )}{κ wt}}$$

Here, L, w and t are the length, width, and thickness, of the constriction, respectively. The Qᵢ values are measured at the nominal sections adjacent to the constriction edges. The convective heat transfer coefficient, h, can be accurately measured from the following equation:

h=kₐᵢᵣ*s,

where s is obtained from fitting the temperature profile of the thermal boundary layer as:

$$ln \frac{T ( y ) - {T}_{∞}}{{T}_{∞} - {T}_{s}} = s * y$$

ΔT can then be determined as follows:

$$Δ T = {T}_{∞} [ {( 1 + \frac{( 1 - α ) {PR}_{th}}{{T}_{∞}} )}^{\frac{1}{1 - α}} - 1 ]$$

With embodiments of the present disclosure, efficiency is a direct function of hot end temperature and not a convex function as in existing materials. Embodiments of the present disclosure can be used for a wide range of hot end temperatures. In comparison, current TE conversion technology and materials exhibit applicability to only narrow temperature limits. Automobiles, electronic systems, heating and air conditioning systems etc. produce waste heat at different temperatures, which makes embodiments of the present disclosure particularly attractive and applicable to a variety of engineering systems without the need for specific modification.

As the change in temperature, ΔT, between at a first point and a second point in a thermoelectric material may characterize a TE conversion device's efficiency, in a preferred embodiment, a device for enhancing thermoelectric conversion of energy may comprise a thermoelectric material having a first section and a second section and the first section may be engaged with the second section at an engagement surface. A difference in temperature as measured from the engagement surface to an end of the second section opposite the engagement area may be between 30° C. and 1000° C. and a cross-sectional area of the second section may be between about 500 nm² and about 5,000 nm².

While a single constriction has some benefits other geometries may be implemented as well. In another preferred embodiment two constrictions were provided. In this embodiment there was a remarkable increase in the ΔT, (186-50) 136° C. Without a constriction, the ΔT would be only 36° C. A 100 fold increase can be extrapolated if the material were not silicon with thermal conductivity of 140 W/m-K but Bi₂Te₃, which has a thermal conductivity of 1.2 W/m-K.

It is believed that a sustainable technology will have normalized efficiency>0.5. This may require ZT>3, but is achievable for ZT=1 if constrictions according to the present disclosure are exploited. For the same hot end temperature value, introduction of constriction can decrease the cold end temperature depending on the constriction size. For the smallest constriction size 0.5 um×0.5 um, the ΔT can be easily doubled. These results show that to achieve the normalized efficiency of 0.5, one does not need ZT>3, in fact ZT=1 will be sufficient if constrictions are used.

A tremendous opportunity exists for high volume and low cost manufacturing by parallel, batch fabrication techniques. This planar design is particularly applicable since nanofabrication processes are planar in nature. According to this design, there is no need to hand-assemble individual n and p legs of a TE conversion device. Also, multi-staging processes are simple, thus a single TE conversion cell (viewed as a p-type leg coupled with an n-type leg) can be produced and reproduced effectively and efficiently. A device having a plurality of TE conversion cells embodying the present disclosure offers few orders of magnitude higher power density than prior art TE conversion devices because miniaturization shrinks individual leg size of a TE conversion cell from a few millimeters to few tens of microns. A minimum of 10,000 unit TE conversion cells per square inches can be achieved, compared to the existing 100 or less values as in the prior art.

A present preferred fabrication process is a derivative of a nano-imprint technique. According to a preferred embodiment, a first paste may be created by mixing n-type bismuth telluride, Bi₂Te₃, nanopowders with TEOS-based binder, such as Tetraethyl orthosilicate and a second paste may be created using p-type antimony telluride, Sb₂Te₃ nanopowders with the TEOS-based binder, such as Tetraethyl orthosilicate, for precision casting. Other n-type, p-type, and binder materials may be used as would be appropriate and understood by one of ordinary skill in the art. The material is then cured at appropriate temperature. In a preferred embodiment, the material is cured at 600K. A second stencil may be used for casting the Sb₂Te₃ legs and associated constrictions. The alternative Sb₂Te₃ legs, once cast, are cured at appropriate temperatures. In a preferred embodiment, the material is cured at 600K. The curing time and temperature may be different in other embodiments, and may depend on the binding agent used. One of ordinary skill in the art would be able to determine the proper curing time for a specific binding agent. During both the creation of the Bi₂Te₃ legs including constrictions and the Sb₂Te₃ legs, including constrictions, the stencils are aligned with the metal interconnects and electrodes. After the legs have been formed material below the legs is removed to create a complete planar TE conversion device. A major difference between TE conversion devices disclosed in the existing literature is that this invention involve freestanding thermoelectric legs that increase the ΔT many-folds and thus offer superior efficiency, whereas prior art TE conversion devices embody only a planar version of traditional design.

The number and size of the cells, and the device comprising the cells, may be varied depending on the desired power output and application of the TE conversion device. Further, the number of devices, which each may contain a plurality of cells, may be varied depending on the desired application. The devices may be arranged in multiple rows and columns such that a sufficient density is present to provide substantial energy conversion characteristics for a desired power output and application.

In another preferred method of manufacture initially, a top layer is a Bi₂Te₃ film, also called the device layer, is electrodeposited on a doped silicon, or the handle layer, on an insulator or buried oxide layer, using the device layer as an electrode. The wafer is then patterned on the top side using electron beam lithography and deep reactive ion etching (“DRIE”). Subsequent etching creates the constriction. A back side alignment and DRIE removes the silicon floor below the specimen. Hydrofluoric (“HF”) acid vapor is used to remove the exposed portion of the oxide layer to have the specimen freestanding in air. Further reduction in constriction size may be accomplished with successive oxidation and HF etching.

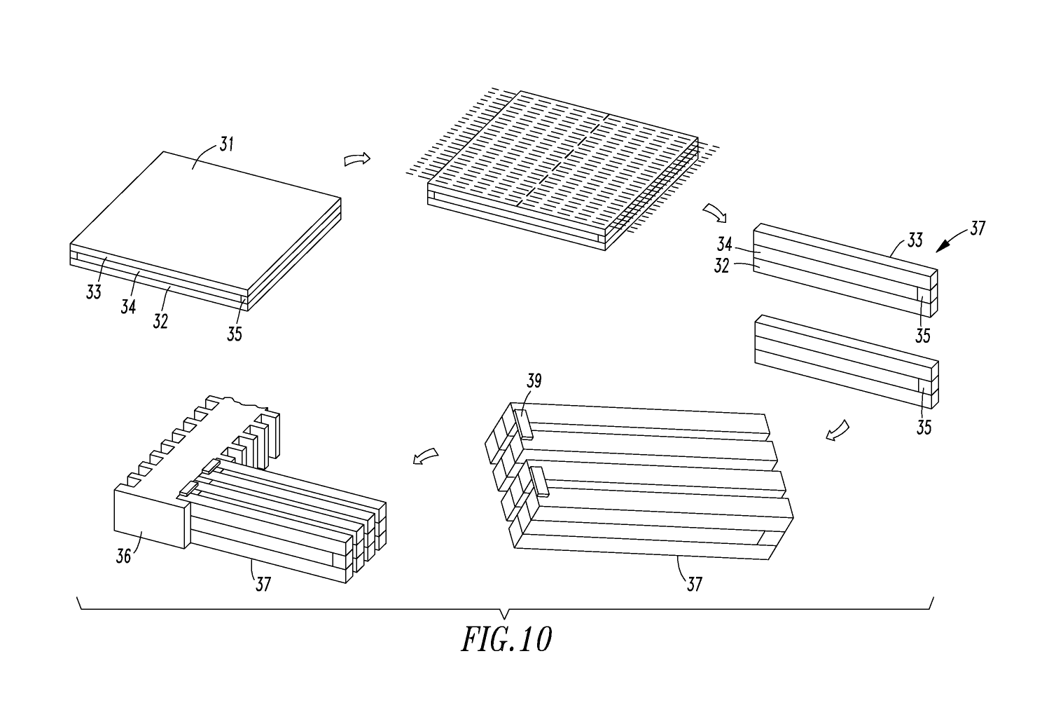

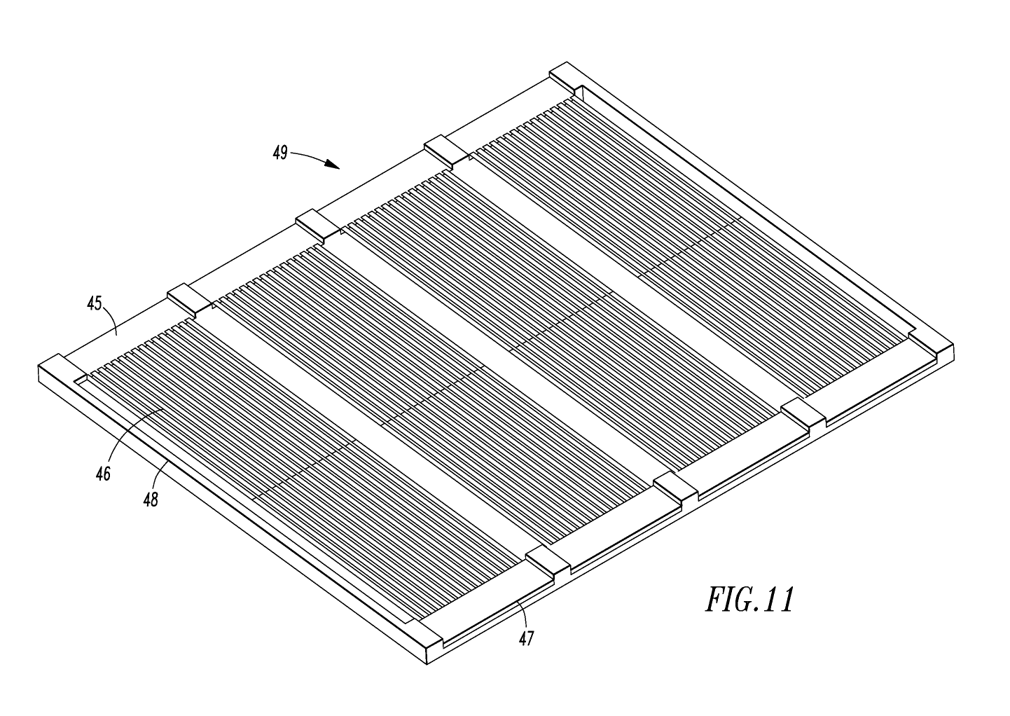

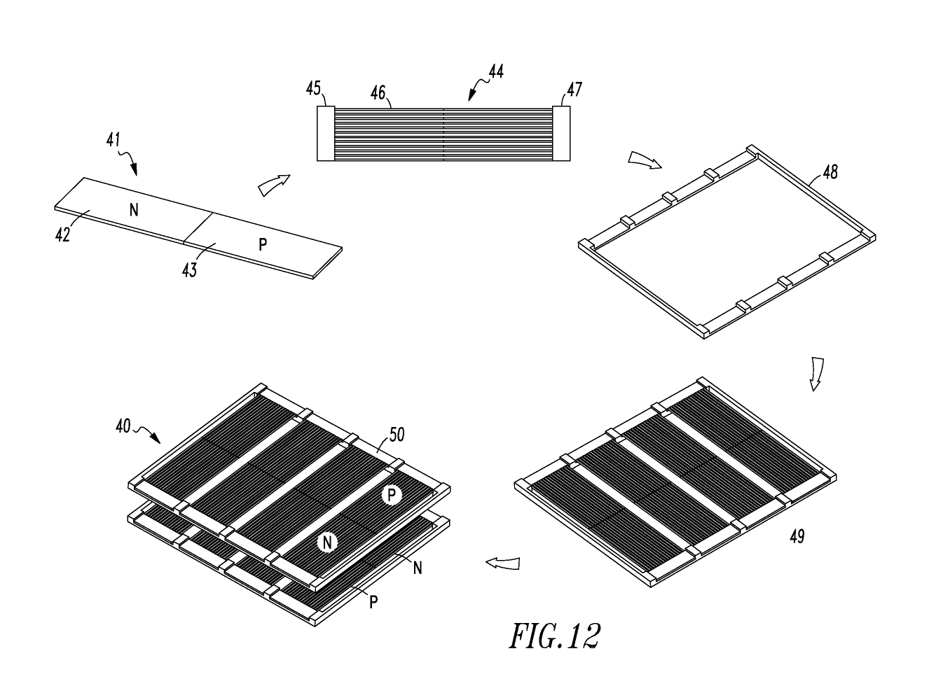

In our efforts to produce our device by screen printing using the process illustrated in FIG. 8 we encountered problems. A very large electrical resistance (40-400 kilo ohms) occurred that led all the generated power to be dissipated as internal loss. This resistance was caused by large voids left behind by the polymeric binding agent after curing it at 300° C. While we believe that the process could work using other materials, we developed two other process illustrated in FIGS. 10 and 12 that produce other embodiments of our device for thermoelectric conversion of energy that are shown in FIGS. 9 and 11.

Referring to FIG. 9, another present preferred embodiment 30 has a housing 36 which is placed on a hot surface (not shown). The housing 36 is preferably an electrical insulator with high thermal conductivity such as alumina or boron nitride. It can also be metallic; in that case a thin coating of electrical insulation is necessary. A series of legs 37 extend from opposite sides of the metal housing 36. Each leg consists of an n-type layer 32 and a p-type layer 33 on opposite surfaces of a non-conductive substrate 34. We prefer to use a glass substrate because it can be chemically etched and removed to create open (air) spaces. The distal end of the n-type layer and a p-type layer are connected by a conductor 35 so that current can flow between and through the n-type layer 32 and the p-type layer 33. The legs 37 are attached to the housing in a manner so that the top layer is alternately an n-type layer and a p-type layer. Adjacent legs 37 are connected by a conductor 39 such that current can flow from one leg to the next leg. The proximate end of each leg attached to the one side metal housing 36 becomes the hot end when the metal plate is attached to a hot structure. The distal end of the legs is free and is the cool end. As indicated by the dotted lines in FIG. 9, the housing 36 may be taller than the legs 37 such that the legs extend from only a portion of the housing.

A present preferred process for making the embodiment 30 is shown in FIG. 10 and begins with a sheet 31 having an n-type layer 32 and a p-type layer 33 on opposite surfaces of a glass or other non-conductive substrate 34. Metal, such as copper or other electrically conductive material, 35 is provided on opposite edges of the sheet 31 between the n-type layer and p-type layer. The sheet is then laser cut as indicated by the broken lines in FIG. 10 to create legs 37. A set of legs is arranged side by side in a spaced apart relationship and a conductor is attached between proximate ends of adjacent legs so the current can flow from one leg to the next leg. The set of legs is attached to one side of the metal housing 36. If desired another set of legs can be attached to the opposite side of the housing. Although the housing 36 is shown to have a rectangular shape in FIGS. 9 and 10, other polygon shapes could be used. Furthermore, more than one set or two sets of legs could be attached to the metal housing 36.

Yet another embodiment 40 has a set of subassemblies 49 that can be stacked and placed on a hot surface. Referring to FIG. 11 each subassembly 49 contains a grate 44 having an n-type portion 42 and a p-type portion 43 that is held on a carrier 48 that conducts heat but does not conduct electricity. Preferably the carrier is alumina. The grate consists of a series of bars 46 that extend between an n-side 45 and a p-side 47. When the subassembly 49 or stack 50 is placed on a hot surface (not shown) these sides become hot, while the center of the bars 46 is cool. The temperature differential causes current to flow from the n-side to the p-side. Leads (not shown) are connected to each side 45, 47 and connected to a load (not shown).

To make the embodiment 40 shown in FIG. 11, one begins with a sheet of material 41 in which half of the sheet is n-type 42 and the other half is p-type 43. Material is removed from the sheet, preferably by laser cutting or by wire saw or by electro-discharge machining, to form a grate 44. The grate 44 consists of a series of bars 46 that extend between an n-side 45 and a p-side 47. The grate 44 is placed on a carrier 48 having an open center to create a subassembly 49. Consequently, air or other fluid can flow freely around and between the bars 46. Two or more subassemblies can be stacked to complete the device.

Embodiments of the present disclosure are not limited to the above-described examples and emphasized aspects but, rather, may appear in a large number of modifications that lie within the scope of handling by a person skilled in the art. It will be apparent to those skilled in the art that numerous modifications and variations of the described examples and embodiments are possible in light of the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this disclosure, which is to be given the full breadth thereof. Additionally, the disclosure of a range of values is a disclosure of every numerical value within that range.

What is claimed is:

1. A device for thermoelectric conversion of energy comprising:
a first metal plate having a bottom surface;
a second metal plate having a bottom surface and spaced apart from the first metal plate;
a metal pad positioned between and spaced apart from the first metal plate and the second metal plate, the metal pad having a bottom surface;
a first insulator attached to the bottom surface of the first plate, the first insulator providing electrical insulation and allowing heat to pass through the first insulator;
a second insulator attached to the bottom surface of the second plate, the second insulator providing electrical insulation and allowing heat to pass through the second insulator;
a first n-type leg having one end attached to the first plate and an opposite end attached to the metal pad;
a first p-type leg having one end attached to the second metal plate and an opposite end attached to the metal pad;
a second n-type leg having one end attached to the first plate and an opposite end attached to the metal pad; and
a second p-type leg having one end attached to the second metal plate and an opposite end attached to the metal pad.

2. The device of claim 1 also comprising a metal pad insulator attached to the bottom surface of the metal pad, the metal pad insulator providing electrical insulation.

3. The device of claim 1 also comprising a first lead attached to the first metal plate and a second lead attached to the second metal plate.

4. The device of claim 1 also comprising a host structure, wherein the first insulator and the second insulator are attached to the host structure and wherein the legs and the metal pad are spaced apart from the host structure.

5. The device of claim 4 wherein the host structure is a silicon wafer.

6. The device of claim 1 wherein the metal pad and metal plates are copper.

7. The device of claim 1 wherein the insulators are silicon nitride.

8. The device of claim 1 wherein at least one of the legs contains at least one constriction.

9. A method for creating a device designed to enhance thermoelectric conversion of energy, the method comprising:
providing a silicon substrate;
vapor depositing a layer of silicon nitride on the silicon substrate;
etching the silicon nitride layer to create a three substantially parallel segments of silicon nitride on the silicon substrate;
depositing copper on each silicon nitride segment thereby creating a first metal plate, a second metal plate and a metal pad between the first metal plate and the second metal plate;
printing a plurality of n-type legs between the first metal plate and the metal pad;
printing a plurality of p-type legs between the second metal plate and the metal pad; and
removing a portion of the silicon substrate from below the metal pad.

10. A device for thermoelectric conversion of energy comprising:
a housing made of a heat conductive material and having multiple sides,
a series of spaced apart legs extending from at least one side of the housing, each leg comprised of an n-type layer and a p-type layer on opposite surfaces of a non-conductive substrate and a conductor connected between the n-type layer and the p-type layer so that current can flow between and through the n-type layer and a p-type layer, the legs being attached to the housing in a manner so that alternately an n-type layer and a p-type layer face in a same direction; and
a plurality of electrically conductive connectors, one connector attached between each pair of adjacent spaced apart legs such that current can flow from one leg to the next leg.

11. The device of claim 10 wherein the substrate is glass.

12. The device of claim 10 wherein at least one of the conductor and the electrically conductive connectors is copper.

13. The device of claim 10 wherein the housing has a first side and a second side opposite the first side and wherein the series of spaced apart legs is comprised of a first set of legs attached to the one side of the housing and a second set of spaced apart legs attached to a second side of the housing.

14. A method for creating a device for thermoelectric conversion of energy, the method comprising:
providing a sheet having an n-type layer and a p-type layer on opposite surfaces of a non-conductive substrate and also having an electrically conductive strip on each of two opposite edges of the sheet and extending between the n-type layer and p-type layer;
cutting the sheet along a first line substantially parallel to the at least one of the edges having the electrically conductive strip and making a series of cuts along cut lines which intersect the first line to create a series of legs;
arranging a set of the legs side by side in a spaced apart relationship;
attaching a conductor between each pair of adjacent legs in the set of legs so the current can flow from one leg to the next leg;
providing a heat conductive housing having multiple sides; and
attaching the set of legs to one side of the heat conductive housing.

15. The method of claim 14 wherein the series of legs is comprised of a first set of legs and a second set of legs and a conductor is attached between each pair of adjacent legs in each set of legs and the first set of legs is attached to the one side of the housing further comprising attaching the second set of legs to another side of the heat conductive housing.

16. A device for thermoelectric conversion of energy comprising:
a carrier having an open center; and
a grate comprised of a series of substantially parallel bars each bar having a first end attached to a first side and a second end attached to a second side and each bar having a portion adjacent the first end which is n-type material and a second portion adjacent the second end which is p-type material, the first side being n-type material and the second side being p-type material;
wherein the grate is attached to the carrier in a manner so that at least a plurality of the bars are over the open center of the carrier.

17. The device of claim 16 also comprising at least one additional device for thermoelectric conversion of energy which is stacked on the device, each of the at least one additional device comprised of:
a carrier having an open center; and
a grate comprised of a series of substantially parallel bars each bar having a first end attached to a first side and a second end attached to a second side and each bar having a portion adjacent the first end which is n-type material and a second portion adjacent the second end which is p-type material, the first side being n-type material and the second side being p-type material;
wherein the grate is attached to the carrier in a manner so that a plurality of the bars extend over the open center of the carrier.

18. A method for creating a device for thermoelectric conversion of energy, the method comprising:
providing a sheet comprised of a first portion of n-type material and a second portion of a p-type material the second portion being adjacent the first portion;
cutting the sheet along a series of substantially parallel lines to create a grate, the grate comprised of a series of substantially parallel bars each bar having a first end attached to a first side and a second end attached to a second side and each bar having a portion adjacent the first end which is n-type material and a second portion adjacent the second end which is p-type material, the first side being n-type material and the second side being p-type material;
providing a carrier having an open center;
attaching the grate to the carrier in a manner so a plurality of the bars are over the open center of the carrier, there by forming the device.

19. The method of claim 18 also comprising repeating the steps of claim 18 to create at least one additional device and stacking the at least one additional device on the device.
